(19) United States
(12) Patent Application Publication
(10) Pub. No.: US 2025/0311107 A1
(43) Pub. Date: Oct. 2, 2025

(54) CIRCUIT BOARD, MANUFACTURING METHOD THEREOF, AND ELECTRONIC COMPONENT PACKAGE INCLUDING THE SAME

(71) Applicant: SAMSUNG ELECTRO-MECHANICS CO., LTD., Suwon-si (KR)

(72) Inventors: Yangje Lee, Suwon-si (KR); Seungju Lee, Suwon-si (KR); Changgon Kim, Suwon-si (KR); Sumin Seo, Suwon-si (KR); Gyeongah Yun, Suwon-si (KR); Kyehwan Ahn, Suwon-si (KR); Yeonji Kim, Suwon-si (KR); Changsoo Choi, Suwon-si (KR)

(73) Assignee: SAMSUNG ELECTRO-MECHANICS CO., LTD., Suwon-si (KR)

(21) Appl. No.: 19/029,293

(22) Filed: Jan. 17, 2025

(30) Foreign Application Priority Data
Mar. 28, 2024 (KR) 10-2024-0042399
Nov. 12, 2024 (KR) 10-2024-0160327

(51) Int. Cl. H05K 1/18; H05K 1/11; H05K 3/18; H05K 3/46

(52) U.S. Cl. CPC H05K 1/186; H05K 1/113; H05K 1/115; H05K 3/181; H05K 3/4644; H05K 2201/09481; H05K 2201/10462; H05K 2203/0384

(57) ABSTRACT

A circuit board may include an insulating layer having a first insulating layer part, a second insulating layer part stacked on the first insulating layer part, and a cavity penetrating a portion of the second insulating layer part and the first insulating layer part, a circuit layer at least partially buried in the second insulating layer part; and a metal pattern layer disposed along the edge of the cavity in the second insulating layer part. The insulating layer has a first surface configuring a bottom surface of the cavity and a second surface configuring a side surface of the cavity, and the metal pattern layer comprises a plurality of metal layers exposed from the insulating layer on the second surface and including different metal.

### CROSS-REFERENCE TO RELATED APPLICATION

This application claims priority to and the benefit of Korean Patent Application No. 10-2024-0160327 filed in the Korean Intellectual Property Office on Nov. 12, 2024, and Korean Patent Application No. 10-2024-0042399 filed in the Korean Intellectual Property Office on Mar. 28, 2024, the entire contents of which are incorporated herein by reference.

### BACKGROUND

### (a) Technical Field

The present disclosure relates to a circuit board, a manufacturing method of the same, and an electronic component package including the same.

### (b) Description of the Related Art

In order to reduce a thickness of a circuit board, a cavity is formed in the circuit board, and various electronic components are placed within the cavity. In this case, the circuit board is required to have a pad of which a surface is exposed through the cavity so that the electronic component may be mounted. However, the circuit board having the cavity may have structural problems such as quality of pad appearance, and it is difficult to simultaneously implement a stopper for processing the cavity and mounting pads on the same layer of the circuit board.

### SUMMARY

An aspect of the present disclosure provides a thinned circuit board and an electronic component package including the same, capable of forming a stopper layer to form a cavity on the same layer and a pad structure exposed from the cavity. However, the problem to be solved by the embodiments of the present disclosure is not limited to the above-described problems, and can be variously extended within the scope of the technical concept included in the present disclosure.

A circuit board according to an embodiment includes an insulating layer having a first insulating layer part, a second insulating layer part stacked on the first insulating layer part, and a cavity penetrating a portion of the second insulating layer part and the first insulating layer part, a circuit layer at least partially buried in the second insulating layer part; and a metal pattern layer disposed along an edge of the cavity in the second insulating layer part. The insulating layer has a first surface configuring a first surface of the cavity and a second surface configuring a side surface of the cavity, the metal pattern layer comprises a plurality of metal layers exposed from the insulating layer on the second surface, and metal layers among the plurality of metal layers include different metals.

The metal layers among the plurality of metal layers may have different etch selectivities with respect to the same material.

The metal pattern layer may be disposed at a corner region of the cavity to connect the first surface of the insulating layer and the second surface of the insulating layer.

The plurality of metal pattern layers may include a first metal layer including copper, and a second metal layer including nickel and disposed on the first metal layer.

The circuit layer may include a first conductive layer disposed on the first insulating layer part and a second conductive layer stacked on the first conductive layer. A surface of the second conductive layer and a surface of the second metal layer may be disposed on substantially the same plane.

The circuit layer may include a first conductive layer including the same material as the first metal layer.

The circuit board according to an embodiment may further include a first pad exposed from the second insulating layer part on the first surface of the insulating layer.

The first pad may be partially buried in the insulating layer.

A surface of the first pad exposed from the second insulating layer part may be positioned further from the first insulating layer part in a stacking direction than a surface of the circuit layer facing the first insulating layer part.

In a stacking direction, a thickness of the first pad may be smaller than a thickness of the circuit layer.

The circuit layer may include a first conductive layer including copper, and a second conductive layer disposed on the first conductive layer.

The first conductive layer may include an electroless plating layer.

The metal pattern layer may concavely position inward from the second surface.

The circuit board according to an embodiment may further include a first pad on the first of the insulating layer. The first pad may be exposed from the insulating layer.

A manufacturing method of a circuit board according to an embodiment includes forming a first stopper layer including a first metal on a first insulating layer part, forming a second stopper layer including a second metal, which is different from the first metal, on the first stopper layer, forming a first pad on the second stopper layer, forming a second insulating layer part including stacking the second insulating layer part on the first insulating layer part to bury the first pad, forming a first cavity forming part including removing a portion of the first insulating layer part on the first stopper layer, wherein the portion of the first insulating layer part has an area in a direction perpendicular to the stacking direction smaller than an area of the first stopper layer, forming a second cavity forming part including removing an exposed portion of the first stopper layer in the first cavity forming part, and forming a cavity including removing an exposed portion of the second stopper layer in the second cavity forming part.

The second metal may have an etch selectivity different from that of the first metal with respect to the same material.

The forming of the second cavity forming part may further include forming a first metal layer remaining along an edge of the first cavity forming part.

The forming of the cavity may further include forming a second metal layer remaining along an edge of the second cavity forming part.

The first metal may include copper, and the second metal may include nickel.

The manufacturing method of a circuit board according to an embodiment may further include forming a circuit layer on the first insulating layer part including forming a first conductive layer on the first insulating layer part, and forming a second conductive layer on the first conductive layer to have a surface at substantially the same level as a surface of the second stopper layer.

The first conductive layer may include the same material as the first stopper layer.

The manufacturing method of a circuit board according to an embodiment may further include forming a circuit layer on the first insulating layer part, wherein the forming of the first pad may include forming the first pad so that a surface of the first pad exposed from the second insulating layer part may be further from the first insulating layer part in a stacking direction than a surface of the circuit layer facing the first insulating layer part.

The manufacturing method of a circuit board according to an embodiment may further include forming a circuit layer on the first insulation layer part, wherein the forming of the first pad may include forming the first pad to have a thickness in a stacking direction smaller than a thickness of the circuit layer in the stacking direction.

The manufacturing method of a circuit board according to an embodiment may further include forming a surface treatment layer on the first pad.

The manufacturing method of a circuit board according to an embodiment may further include forming a circuit layer on the first insulating layer part including forming a first conductive layer including copper and forming a second conductive layer on the first conductive layer.

The forming of the first conductive layer may include forming an electroless plating layer.

The manufacturing method of a circuit board according to an embodiment may further include forming a first metal layer including etching the first stopper layer so that the first metal layer is inward from a side surface of the second insulating layer part.

The manufacturing method of a circuit board according to an embodiment may further include forming a second metal layer including etching the second stopper layer so that the second stopper layer is inward from a side surface of the second insulating layer part.

The first insulating layer part and the second insulating layer part together may form an insulating layer, and the cavity is formed on a surface of the insulating layer, and the manufacturing method may further include forming a second pad on a surface of the insulating layer such that the second pad is exposed from the insulating layer.

An electronic component package according to an embodiment includes a circuit board including an insulating layer having a cavity, a pad part exposed from the insulating layer, a circuit layer at least partially buried in the insulating layer, and a metal pattern layer disposed along an edge of the cavity in the insulating layer. The insulating layer has a first surface configuring a first surface of the cavity and a second surface configuring a side surface of the cavity, the metal pattern layer comprises a plurality of metal layers exposed from the insulating layer on the second surface, and metal layers among the plurality of metal layers include different metal, and an electronic component mounted in the cavity to be connected to the pad part.

The plurality of metal layers may include a first metal layer including copper, and a second metal layer including nickel and disposed on the first metal layer.

A circuit board according to an embodiment includes an insulating layer having a first insulating layer part, a second insulating layer part stacked on the first insulating layer part, and a cavity penetrating a portion of the second insulating layer part and the first insulating layer part, a circuit layer at least partially buried in the second insulating layer part; and a metal pattern layer disposed along an edge of the cavity in the second insulating layer part. The insulating layer has a first surface configuring a first surface of the cavity and a second surface configuring a side surface of the cavity, a first distance between side surfaces of the cavity at an opening of the cavity is substantially the same as a second distance between the side surfaces of the cavity adjacent to the first surface of the cavity, the metal pattern layer comprises a plurality of metal layers exposed from the insulating layer on the second surface, and metal layers among the plurality of metal layers include different metals.

The metal layers among the plurality of metal layers may have different etch selectivities with respect to the same material.

The metal pattern layer may be disposed at a corner region of the cavity to connect the first surface of the insulating layer and the second surface of the insulating layer.

The plurality of metal pattern layers may include a first metal layer including copper, and a second metal layer including nickel and disposed on the first metal layer.

A manufacturing method of a circuit board according to an embodiment includes forming a first stopper layer including a first metal on a first insulating layer part, forming a second stopper layer including a second metal, which is different from the first metal, on the first stopper layer, forming a first pad on the second stopper layer, forming a second insulating layer part including stacking the second insulating layer part on the first insulating layer part to bury the first pad, forming a first cavity forming part including removing a portion of the first insulating layer part on the first stopper layer, wherein the portion of the first insulating layer part has an area in a direction perpendicular to the stacking direction smaller than an area of the first stopper layer, forming a second cavity forming part including removing an exposed portion of the first stopper layer in the first cavity forming part, and forming a cavity including removing an exposed portion of the second stopper layer in the second cavity forming part. A first distance between side surfaces of the cavity at an opening of the cavity is substantially the same as a second distance between the side surfaces of the cavity adjacent to a surface of the cavity opposing the opening of the cavity.

The second metal may have an etch selectivity different from that of the first metal with respect to the same material, the first metal may include copper, and the second metal may include nickel.

The forming of the second cavity forming part may further include forming a first metal layer remaining along an edge of the first cavity forming part.

The forming of the cavity may further include forming a second metal layer remaining along an edge of the second cavity forming part.

According to an embodiment of a circuit board, a method of manufacturing the circuit board, and an electronic component package, the cavity structure and the pad structure exposed in the cavity may be more easily formed by using a plurality of metal layers including different metals as the etch stopper layer, and the circuit board with a thin thickness may be provided, thereby thinning the electronic products mounted on the circuit board.

### BRIEF DESCRIPTION OF THE DRAWINGS

FIG. 1 is a cross-sectional view schematically illustrating a circuit board according to an embodiment.

FIG. 2 is an enlarged cross-sectional view according to an example of area A of FIG. 1.

FIG. 3 is an enlarged cross-sectional view according to an example of area B of FIG. 1.

FIG. 4 to FIG. 16 are cross-sectional views illustrating a manufacturing method of a circuit board according to an embodiment.

FIG. 17 is a cross-sectional view schematically illustrating an electronic component package according to an embodiment.

### DETAILED DESCRIPTION

Hereinafter, various embodiments of the present disclosure will be described in detail so that a person of ordinary skill in the technical field to which the present disclosure belongs can easily implement it with reference to the accompanying drawings. In order to clearly describe the present disclosure, parts unrelated to the description are omitted in the drawings, and the same reference numerals are designated to the same or similar elements throughout the specification. In addition, some elements in the accompanying drawings are exaggerated, omitted, or schematically illustrated, and the size of each element does not fully reflect the actual size.

The accompanying drawings are provided only in order to allow embodiments disclosed in the present specification to be easily understood and are not to be interpreted as limiting the technical concept disclosed in the present specification, and it is to be understood that the present disclosure includes all modifications, equivalents, and substitutions included in the concept and technical scope of the present disclosure.

Terms including ordinal numbers such as first, second, and the like will be used only to describe various elements and are not to be interpreted as limiting these elements. The terms are only used to differentiate one element from other elements.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Furthermore, in the specification, the word “on” or “above” means positioned on or below the object portion and does not necessarily mean positioned on the upper side of the object portion based on a gravitational direction.

It will be further understood that terms “comprises/includes” or “have” used throughout the specification specify the presence of stated features, numerals, steps, operations, elements, parts, or a combination thereof, but do not preclude the presence or addition of one or more other features, numerals, steps, operations, elements, parts, or a combination thereof. Accordingly, unless explicitly described to the contrary, the word “comprise” and variations such as “comprises” or “comprising” will be understood to imply the inclusion of stated elements but not the exclusion of any other elements.

Further, throughout the specification, the phrase “in a plan view” means when an object portion is viewed from above, and the phrase “in a cross-sectional view” means when a cross-section taken by vertically cutting an object portion is viewed from the side.

Throughout the specification, “connected” means that two or more elements are not only directly connected, but two or more elements may be connected indirectly through other elements, physically connected as well as being electrically connected, or it may be referred to by different names depending on the location or function but may mean integral.

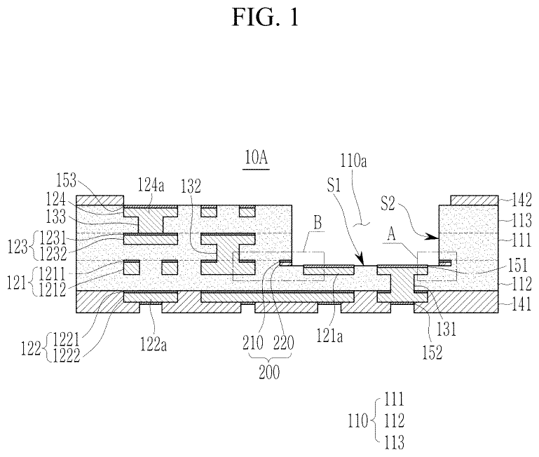

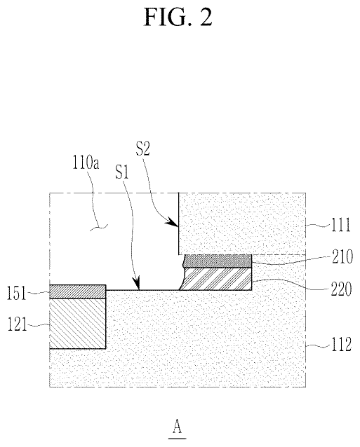

Hereinafter, A circuit board 10A according to an embodiment will be described with reference to FIG. 1 and FIG. 2.

FIG. 1 illustrates a cross-sectional view schematically illustrating a circuit board according to an embodiment. Referring to FIG. 1, the circuit board 10A according to an embodiment may include an insulating layer 110 including a first insulating layer part 111 and a second insulating layer part 112, a first circuit layer 121, and metal pattern layer 200. The second insulating layer part 112 may be stacked on the first insulating layer part 111. The insulating layer 110 may have a cavity 110a penetrating a portion of the second insulating layer part 112 and the first insulating layer part 111. The first circuit layer 121 may be at least partially buried in the second insulating layer part 112. The metal pattern layer 200 may be disposed along the edge of the cavity 110a in the second insulating layer part 112. The insulating layer 110 may have a first surface S1 configuring a bottom surface of the cavity 110a and a second surface S2 configuring a side surface of the cavity 110a. The metal pattern layer 200 may be exposed from the insulating layer 110 on the second surface S2 and may comprise a plurality of metal layers including different metal.

The insulating layer 110 may be a structure in which a plurality of layers are stacked. As an example, the insulating layer 110 may include the first insulating layer part 111, the second insulating layer part 112, and a third insulating layer part 113. The second insulating layer part 112 may be stacked on a surface of the first insulating layer part 111. The third insulating layer part 113 may be stacked on the other surface of the first insulating layer part 111. The third insulating layer part 113 may be disposed opposite to the second insulating layer part 112. The insulating layer 100 may include an insulating material. The insulating material may include a thermosetting resin such as an epoxy resin, a thermoplastic resin such as polyimide, or these resins including an inorganic filler such as silica and a reinforcing material such as glass fiber. The insulating material may be a photosensitive material or non-photosensitive material. For example, Solder Resist (SR), Ajinomoto-Build up Film (ABF), FR-4, Bismaleimide Triazine (BT), Resin Coated Copper (RCC) or Copper Clad Laminate (CCL), etc. may be used as the insulating material, but are not limited thereto. The insulating material may include a polymer material. Meanwhile, these resins including an inorganic filler such as silica and a reinforcing material such as glass fiber, etc. may be used as the material of the insulating layer 110. For example, a prepreg may be used, but is not limited thereto. In addition, the insulating layer 110 is shown as three layers in FIG. 1, but is not limited thereto, the insulating layer 110 may include single or plurality of insulating layer part.

The circuit board 10A according to an embodiment may include plurality of circuit layers. For example, the circuit board 10A according to an embodiment may include a first to a fourth circuit layer 121, 122, 123, and 124. Each of the first to the fourth circuit layer 121, 122, 123, and 124 may be buried in the insulating layer 110 or disposed on the insulating layer 110.

The first circuit layer 121 may be disposed on the surface of the first insulating layer part 111. The first circuit layer 121 may be at least partially buried in the second insulating layer part 112. The second circuit layer 122 may be positioned on the second insulating layer part 112. The second circuit layer 122 may be positioned on a surface of the insulating layer 110. A third circuit layer 123 may be positioned on a surface of the third insulating layer part 113. The third circuit layer 123 may be at least partially buried in the first insulating layer part 111. The fourth circuit layer 124 may be positioned on the other surface of the third insulating layer part 113. The fourth circuit layer 124 may be at least partially exposed on the other surface of the insulating layer 110. The fourth circuit layer 124 may be at least partially buried in the third insulating layer part 113.

A portion of the first circuit layer 121 may function as a pad for connection with other substrates or components. The first circuit layer 121 may include a first pad 121a exposed from the other surface of the second insulating layer part 112 to the outside of the insulating layer 110. The first pad 121a may be partially buried in the second insulating layer part 112, but is not limited thereto. The first pad 121a may be disposed on the surface of the first insulating layer part 111 to protrude from the surface.

A portion of the second circuit layer 122 may function as a pad for connection with other substrates or components. The second circuit layer 122 may include a second pad 122a exposed from a surface of the second insulating layer part 112 to the outside of the insulating layer 110. The second pad 122a may be disposed on the surface of the insulating layer 110. The second pad 122a may be disposed on the surface of the second insulating layer part 112 to protrude from the surface, but is not limited thereto. The second pad 122a may be partially buried in the second insulating layer part 112.

A portion of the fourth circuit layer 124 may function as a pad for connection with other substrates or components. The fourth circuit layer 124 may include a third pad 124a exposed from the other surface of the third insulating layer part 113 to the outside of the insulating layer 110. The third pad 124a may be partially buried in the third insulating layer part 113, but is not limited thereto. The third pad 124a may be disposed on the other surface of the third insulating layer part 113 to protrude from the other surface.

The first pad 121a may include an electro plating layer. The first pad 121a may be formed as a single layer. The second pad 122a may include an electroless plating layer and an electro plating layer. The second pad 122a may include a plurality of layers. The third pad 124a may include an electro plating layer. The third pad 124a may be formed as a single layer.

The first to fourth circuit layers 121, 122, 123, and 124 are shown in FIG. 1, but are not limited thereto, a greater number of circuit layers than illustrated may be disposed, or a lesser number of circuit layers may also be disposed.

Each of the first to fourth circuit layers 121, 122, 123, and 124 may transfer a signal inside the circuit board 10A. A metal material may be used as a material for each of the first to fourth circuit layers 121, 122, 123, and 124. The metal material may include copper (Cu), aluminum (Al), silver (Ag), tin (Sn), gold (Au), nickel (Ni), lead (Pb), titanium (Ti), or an alloy thereof. Each of the first to fourth circuit layers 121, 122, 123, and 124 may perform various functions depending on a design thereof, such as ground pattern, power pattern, signal pattern, etc. Each of these patterns may have a line shape, a plane shape, or a pad shape. In the case of a circuit layer positioned in the outermost layer among the plurality of circuit layers, it may function as a pad for connection to another board or component.

Each of the first to the fourth circuit layer 121, 122, 123, and 124 may be formed by a wire forming process, for example, an Additive Process (AP), a Semi AP (SAP), a Modified SAP (MSAP), or a tenting (TT) process. Each of the first to the third circuit layer 121, 122, and 123 may include seed layer, which is an electroless plating layer, and an electro plating layer formed based on the seed layer. The fourth circuit layer 124 may include an electro plating layer.

The first circuit layer 121 may include a first conductive layer 1211 disposed on the surface of the first insulating layer part 111 and a second conductive layer 1212 stacked on the first conductive layer 1211. The first conductive layer 1211 may include an electroless plating layer, and the second conductive layer 1212 may include electro plating layer, but is not limited thereto. The second circuit layer 122 may include a third conductive layer 1221 disposed on the second insulating layer part 112, and a fourth conductive layer 1222 stacked on the third conductive layer 1221. The third conductive layer 1221 may include an electroless plating layer, and the fourth conductive layer 1222 may include an electro plating layer, but is not limited thereto. The third circuit layer 123 may include a fifth conductive layer 1231 disposed on the third insulating layer part 113, and a sixth conductive layer 1232 stacked on the fifth conductive layer 1231. The fifth conductive layer 1231 may include an electroless plating layer, and the sixth conductive layer 1232 may include an electro plating layer, but is not limited thereto. The electroless plating layer may be a chemical copper plating layer, but is not limited thereto, and may be, for example, a sputtering layer.

The circuit board 10A according to an embodiment may include a first via electrode 131 penetrating the second insulating layer part 112 and electrically connecting the first circuit layer 121 and the second circuit layer 122, a second via electrode 132 penetrating the first insulating layer part 111 and electrically connecting the first circuit layer 121 to the third circuit layer 123, and a third via electrode 133 penetrating the third insulating layer part 113 and electrically connecting the third circuit layer 123 to the fourth circuit layer 124. In FIG. 1, the first to the third via electrodes 131, 132, and 133 are each illustrated in a singular, but are not limited thereto, and the first to the third via electrodes 131, 132, 133 may be provided in plural, respectively.

A metal material may be used as a material of each of the first to the third via electrodes 131, 132, and 133. For the metal material, copper (Cu), aluminum (Al), silver (Ag), tin (Sn), gold (Au), nickel (Ni), lead (Pb), titanium (Ti), or alloys thereof may be used. Each of the first to the third via electrodes 131, 132, and 133 may include a signal via, a ground via, a power via, and the like according to a circuit design. Each of the first to the third via electrodes 131, 132, and 133 may be formed by filling a via hole with a metal material, or by disposing the metal material along a wall of the via hole. Each of the plurality of via electrodes 131, 132, and 133 may formed by a plating process. For example, each of the first to the third via electrodes 131, 132, and 133 may have a tapered shape in which a width of a surface is smaller than a width of the other surface.

Meanwhile, in FIG. 1, the circuit board 10A according to an embodiment is illustrated to include first to the third via electrodes 131, 132, and 133, but depending on the configuration of the insulating layer 110 and the design of the circuit layer, an via layer in which the via electrode is disposed may be composed of a single layer or more layers

The circuit board 10A according to an embodiment may include a first passivation layer 141 and a second passivation layer 142. Each of the first passivation layer 141 and the second passivation layer 142 may protect the internal component from external physical and chemical damage and the like. The first passivation layer 141 may disposed on the insulating layer 110.

The first passivation layer 141 may be opened to cover the surface of the insulating layer 110 and expose at least a portion of the second circuit layer 122. The first passivation layer 141 may have at least one opening. The first passivation layer 141 may include photosensitivity resin. The first passivation layer 141 may be a solder resist layer.

The second passivation layer 142 may be disposed on the other surface of the insulating layer 110. The second passivation layer 142 may cover the other surface of the insulating layer 110, and may be opened to expose at least a portion of the fourth circuit layer 124. The second passivation layer 142 may have at least one opening. The second passivation layer 142 may include a photosensitivity resin. The second passivation layer 142 may be a solder resist layer.

The circuit board 10A according to an embodiment may include a first to a third surface treatment layers 151, 152, and 153 covering a portion of the circuit layer exposed to the outside of the insulating layer 110. The first surface treatment layer 151 may be disposed on the first pad 121a. The second surface treatment layer 152 may be disposed on the second pad 122a. The third surface treatment layer 153 may be disposed on the third pad 124a. The first to the third surface treatment layers 151, 152, and 153 may include any one of nickel (Ni), palladium (Pd), and gold (Au), and a plurality of these metal layers may be implemented. Meanwhile, the first to the third surface treatment layers 151, 152, and 153 are not limited thereto, and may include an organic material. The first to the third surface treatment layers 151, 152, and 153 may improve a coupling force and a signal transmission force of the first to the third pads 121a, 122a, and 124a and a configuration mounted on the first to the third pads 121a, 122a, and 124a.

The insulating layer 110 may have the cavity 110a penetrating a portion of the second insulating layer part 112 and the first insulating layer part 111. The circuit board 10A according to an embodiment may include the metal pattern layer 200 disposed along the edge of the cavity 110a in the second insulating layer part 112. The insulating layer 110 may have a first surface S1 configuring a bottom surface of the cavity 110a and a second surface S2 configuring a side surface of the cavity 110a. The first pad 121a may be exposed from the second insulating layer part 112 on the first surface S1.

The metal pattern layer 200 may be exposed from the insulating layer 110 on the second surface S2. The metal pattern layer 200 may include plurality of metal layers. The plurality of metal layers may include different metal respectively.

Hereinafter, the metal pattern layer 200 of the circuit board 10A according to an embodiment will be described in detail with reference to FIG. 1 to FIG. 3.

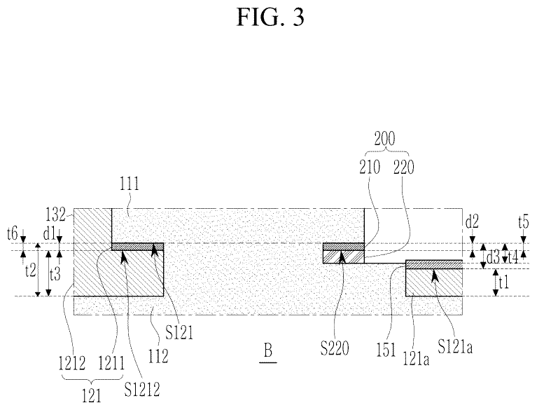

FIG. 2 is an enlarged cross-sectional view according to an example of area A of FIG. 1. FIG. 3 is an enlarged cross-sectional view according to an example of area B of FIG. 1.

Referring to FIG. 1 to FIG. 3, the metal pattern layer 200 may be disposed to connect the first surface S1 and the second surface S2. The metal pattern layer 200 may be disposed at corner region of the cavity 110a. The metal pattern layer 200 may be disposed to surround the cavity 110a. The metal pattern layer 200 may be disposed to surround the first surface S1.

The metal pattern layer 200 may include a first metal layer 210 and a second metal layer 220. The first metal layer 210 may be disposed on the surface of the first insulating layer part 111. The second metal layer 220 may be disposed on a surface of the first metal layer 210. A surface of the second metal layer 220 may be in contact with the first surface S1.

Each of the first metal layer 210 and the second metal layer 220 may include a different metal. Each of the first metal layer 210 and the second metal layer 220 may have different etch selectivity for the same material. For example, the first metal layer 210 may include copper (Cu), the second metal layer 220 may include nickel (Ni), but is not limited thereto, any metals that allow the first metal layer 210 and the second metal layer 220 to have different etch selectivity for the same material may be used. Etch selectivity may mean a ratio of an etch rate of material X to an etch rate of material Y. Here, material X may be a material desired to be etched, and material Y may be a material not desired to be etched (mask layer, etc.).

For example, the first metal layer 210 and the first conductive layer 1211 may be formed by the same process. The first metal layer 210 may include the same material as the first conductive layer 1211. The first metal layer 210 and the first conductive layer 1211 may include the same material including copper (Cu). Furthermore, the first metal layer 210 may include the same material as the third conductive layer 1221 and the fifth conductive layer 1231. The first metal layer 210, the third conductive layer 1221, and the fifth conductive layer 1231 may include the same material including copper (Cu). Thus, the second metal layer 220 may include a material different from that of the first conductive layer 1211. The second metal layer 220 may include a material different from that of the third conductive layer 1221 and the fifth conductive layer 1231.

Referring to FIG. 2, the metal pattern layer 200 may be positioned inward from the second surface S2, in a direction perpendicular to the stacking direction. The metal pattern layer 200 may be concavely positioned inward from the second surface S2. An edge of the metal pattern layer 200 may include a portion inserted inward from the second surface S2. A surface of the metal pattern layer 200 exposed toward the cavity 110a may include an inclined surface with respect to a reference line parallel to the stacking direction. The inclined surface of the metal pattern layer 200 may be a curved surface. For example, the metal pattern layer 200 may have the inclined surface of the curved surface by wet etching process. An edge of the first metal layer 210 may be a shape to be inward from the second surface S2. A surface of the first metal layer 210 exposed toward the cavity 110a may include an inclined surface with respect to a reference line parallel to the stacking direction. The inclined surface of the first metal layer 210 may be a curved surface. An edge of the second metal layer 220 may be a shape to be inward from the second surface S2. A surface of the second metal layer 220 exposed toward the cavity 110a may include an inclined surface with respect to a reference line parallel to the stacking direction. The inclined surface of the second metal layer 220 may be a curved surface.

Referring to FIG. 3, a lower surface S1212 of the second conductive layer 1212 may be disposed on substantially the same level as a lower surface S220 of the second metal layer 220. The second conductive layer 1212 may be disposed on substantially the same plane as the second metal layer 220. The lower surface S1212 of the second conductive layer 1212 and the lower surface S220 of the second metal layer 220 may be positioned at substantially the same distance from an upper surface of the first insulating layer part 111. A distance d1 from the upper surface of the first insulating layer part 111 to the lower surface S1212 of the second conductive layer 1212 may be substantially the same as a distance d2 from the upper surface of the first insulating layer part 111 to the lower surface S220 of the second metal layer 220. As used herein, the expression “substantially the same” may refer to being at the same height level or having the same distance or thickness relative to the height level or distance or thickness compared therewith, as will be appreciated by those of skill in the art, and allows for approximations, inaccuracies and limits of measurement under the relevant circumstances. In one or more aspects, the term “substantially” may provide an industry-accepted tolerance for the corresponding terms and/or relativity between items, such as a tolerance of ±1%, ±5%, or ±10% of the actual value stated, and other suitable tolerances. The expression “substantially the same plane” may refer to planes having an angle of 0° to 5° with respect to each other. The height, distance, and thickness may be determined by an optical microscope or a scanning electron microscope. Other methods and/or tools appreciated by one of ordinary skill in the art, even if not described in the present disclosure, may also be used.

A lower surface S121a of the first pad 121a may be positioned at a greater distance than a lower surface S121 of the first circuit layer 121 from the upper surface of the first insulating layer part 111 in the stacking direction. A surface of the first pad 121a exposed from the second insulating layer part 112 may be positioned further than a surface of the first circuit layer 121 facing the first insulating layer part 111, with respect to a distance in the stacking direction from the first insulating layer part 111.

The lower surface S121a of the first pad 121a may be positioned at a greater distance than the lower surface S220 of the second metal layer 220 from the upper surface of the first insulating layer part 111 in the stacking direction. A distance d3 from the upper surface of the first insulating layer part 111 to the lower surface S121a of the first pad 121a may be greater than the distance d2 from the upper surface of the first insulating layer part 111 to the lower surface S220 of the second metal layer 220.

The surface of the first pad 121a exposed from the second insulating layer part 112 may be positioned further than a surface of the second metal layer 220 facing the first insulating layer part 111, with respect to a distance in the stacking direction from the first insulating layer part 111.

Referring to FIG. 3, a thickness t1 of the first pad 121a may be smaller than a thickness t2 of the first circuit layer 121, with respect to a thickness in the stacking direction. The thickness t1 of the first pad 121a may be smaller than a thickness t3 of the second conductive layer 1212, with respect to a thickness in the stacking direction. A thickness t4 of the metal pattern layer 200 may be smaller than the thickness t2 of the first circuit layer 121, with respect to a thickness in the stacking direction. A thickness t5 of the first metal layer 210 and a thickness t6 of the first conductive layer 1211 may be substantially the same, with respect to a thickness in the stacking direction. The thicknesses described herein may be determined by an optical microscope or a scanning electron microscope. Other methods and/or tools appreciated by one of ordinary skill in the art, even if not described in the present disclosure, may also be used.

According to an embodiment of a circuit board, a cavity structure and a pad structure exposed from the cavity may be formed more easily using a plurality of metal layers each including a different metal as an etch stopper layer. And an electronic component package in which the circuit board is mounted may be thinned, since the circuit board having a thin thickness may be provided.

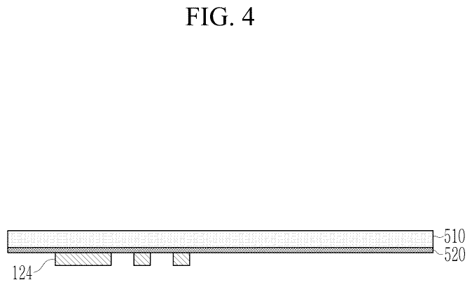

Hereinafter, a manufacturing method for a circuit board 10A according to an embodiment will be described with reference to FIG. 4 to FIG. 17.

FIG. 4 to FIG. 16 are cross-sectional views illustrating a manufacturing method for a circuit board according to an embodiment.

Referring to FIG. 4, a carrier board, which is a base material for manufacturing the circuit board 10A, may be prepared. The carrier board may include a carrier insulating layer 510 and a carrier conductive layer 520 disposed on a surface of the carrier insulating layer 510. The carrier conductive layer 520 may be disposed on a surface of the carrier insulating layer 510, and alternatively, may be disposed on both surfaces. In case the carrier conductive layer 520 is disposed on both sides of the carrier insulating layer 510, in the following process, a circuit board manufacturing process may be performed on both sides of the carrier board until the carrier board is removed. The carrier conductive layer 520 may be formed by performing electroless plating on a surface of the carrier insulating layer 510.

In addition, referring to FIG. 4, the fourth circuit layer 124 may be formed on the carrier conductive layer 520. The fourth circuit layer 124 may be formed by a plating process. For example, the fourth circuit layer 124 may be formed by forming a photoresist on the carrier conductive layer 520, patterning the photoresist through exposure and development processes, plating and filling the patterned area, and peeling the photoresist. However, the process is not limited thereto, and any method capable of configuring a pattern on a circuit board may be used without limitation.

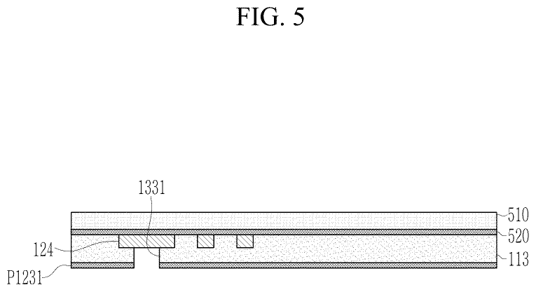

Referring to FIG. 5, the third insulating layer part 113 may be formed to bury the carrier conductive layer 520 and the fourth circuit layer 124. The third insulating layer part 113 may be formed of a material such as a Prepreg (PPG), an Ajinomoto Build-up Film (ABF), and a Resin Coated Copper foil (RCC).

Referring to FIG. 5, a third via hole 1331 may be formed through the third insulating layer part 113. The third via hole 1331 may be formed by laser processing, mechanical drill processing, or the like.

In addition, a fifth conductive forming layer P1231 may be formed on a surface of the third insulating layer part 113. The fifth conductive forming layer P1231 may be formed by performing electroless plating on a surface of the third insulating layer part 113. In FIG. 5, the fifth conductive forming layer P1231, which is an electroless plating layer, is illustrated to be formed only on a surface of the third insulating layer part 113, the electroless plating layer may also be formed on the inner surface of the third via hole 1331.

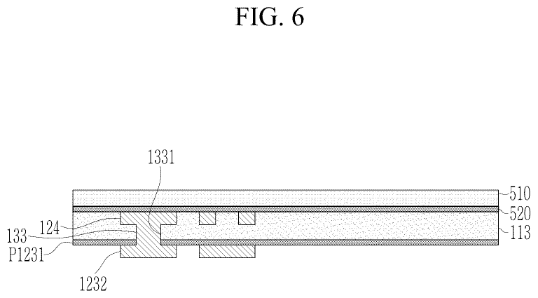

Referring to FIG. 6, the sixth conductive layer 1232 may be formed on the fifth conductive forming layer P1231. The sixth conductive layer 1232 may be formed by a plating process. Furthermore, the third via electrode 133 may be formed by filling a conductive material in the third via hole 1331.

For example, the sixth conductive layer 1232 and the third via electrode 133 may be formed by forming a photoresist on the fifth conductive forming layer P1231, patterning the photoresist through exposure and development processes, plating and filling the patterned area, and peeling the photoresist. However, the process is not limited thereto, and any method capable of configuring a pattern on a circuit board may be used without limitation.

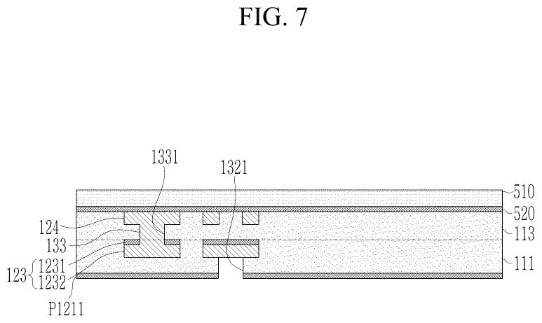

Referring to FIG. 7, the fifth conductive layer 1231 may be formed by removing a portion of the fifth conductive forming layer P1231. Accordingly, the third circuit layer 123 including the fifth conductive layer 1231 and the sixth conductive layer 1232 may be formed. For example, the fifth conductive forming layer P1231 may be removed by flash etching.

Then, the first insulating layer part 111 may be formed to bury the fifth conductive layer 1231 and the sixth conductive layer 1232. The first insulating layer part 111 may be formed of a material such as a prepreg (PPG), an Ajinomoto build-up film (ABF), and a Resin Coated Copper foil (RCC).

Furthermore, referring to FIG. 7, a second via hole 1321 may be formed to penetrate a first conductive forming layer P1211 and the first insulating layer part 111. The second via hole 1321 may be formed by laser processing, mechanical drill processing, or the like

In addition, the first conductive forming layer P1211 may be formed on the surface of the first insulating layer part 111. The first conductive forming layer P1211 may be formed by performing electroless plating on the surface of the first insulating layer part 111. In FIG. 7, the first conductive forming layer P1211, which is an electroless plating layer, is illustrated to be formed only on the surface of the first insulating layer part 111, the electroless plating layer may also be formed on the inner surface of the second via hole 1321.

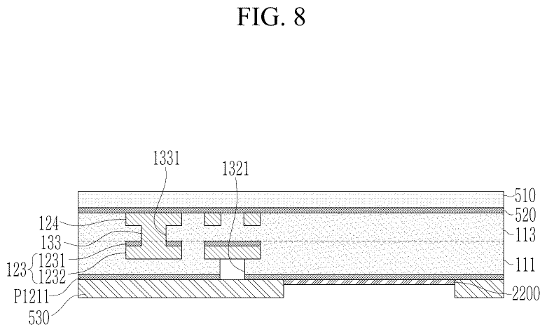

Referring to FIG. 8, a mask layer 530 may be formed on a surface of the first conductive forming layer P1211. Specifically, the mask layer 530 may be formed on portions other than a region in which the second stopper layer 2200 is to be formed. The mask layer 530 may be formed to include a dry film.

In addition, the second stopper layer 2200 may be formed on the first insulating layer part 111. The second stopper layer 2200 may be formed to include a second metal. For example, the second metal may include nickel (Ni). The second stopper layer 2200 may be formed on the first conductive forming layer P1211. The first conductive forming layer P1211 may include a first metal different from the second metal. For example, the first metal may include copper (Cu).

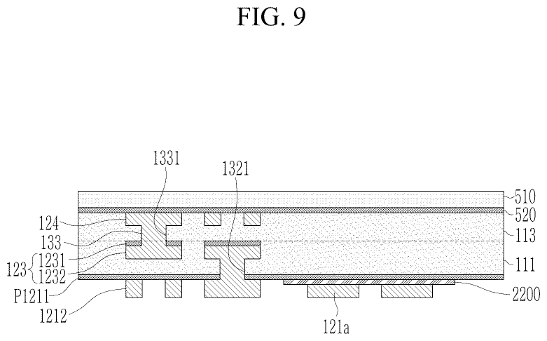

Referring to FIG. 9, the second via electrode 132 may be formed by filling a conductive material in the second via hole 1321.

Furthermore, referring to FIG. 9, the mask layer 530 may be removed, and the second conductive layer 1212 may be formed on a portion of the first conductive forming layer P1211 and the second stopper layer 2200. The second conductive layer 1212 may be formed by a plating process. The second conductive layer 1212 may be formed such that the lower surface S1212 of the second conductive layer 1212 has substantially the same level as a lower surface of the second stopper layer 2200. The lower surface S1212 of the second conductive layer 1212 and the lower surface of the second stopper layer 2200 may be positioned at substantially the same distance from the upper surface of the first insulating layer part 111.

For example, the second conductive layer 1212 may be formed by forming a photoresist on the first conductive forming layer P1211, patterning the photoresist through exposure and development processes, plating and filling the patterned area, and peeling the photoresist. However, the process is not limited thereto, and any method capable of configuring a pattern on a circuit board may be used without limitation.

Here, the second conductive layer 1212 may be formed to include a first pad 121a. The first pad 121a may be formed on the second stopper layer 2200. The second conductive layer 1212 may be formed to include the first pad 121a and a pattern part disposed around the first pad 121a. The first pad 121a may be formed to include a portion of the second conductive layer 1212.

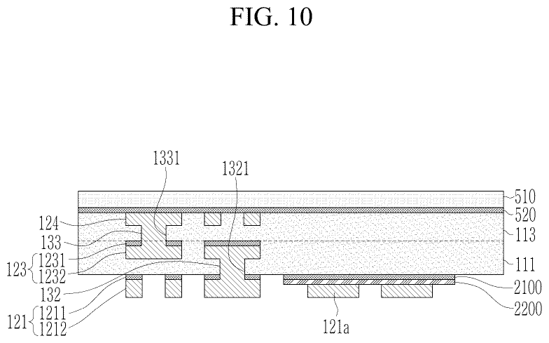

Referring to FIG. 10, a first conductive layer 1211 and the first stopper layer 2100 may be formed by removing a portion of the first conductive forming layer P1211. The first conductive layer 1211 may be formed to include the same material as the first stopper layer 2100. Accordingly, a first circuit layer 121 including the first conductive layer 1211 and the second conductive layer 1212 may be formed on the first insulating layer part 111.

The first pad 121a may be formed such that the lower surface S121a of the first pad 121a is positioned at a higher level than a lower surface S121 of the first circuit layer 121 in a stacking direction. The first pad 121a may be formed such that the lower surface S121a of the first pad 121a is positioned at a greater distance than the lower surface S121 of the first circuit layer 121 from the upper surface of the first insulating layer part 111.

For example, the first conductive layer 1211 may be removed by flash etching.

The first stopper layer 2100 may be formed to include the first metal. The first metal may be a material having etch selectivity different from that of the second metal for the same material. The first metal may include copper (Cu).

The first stopper layer 2100 may be formed on the first insulating layer part 111. The first stopper layer 2100 may have a shape corresponding to the second stopper layer 2200. The first stopper layer 2100 may be overlapped with the second stopper layer 2200 in a stacking direction.

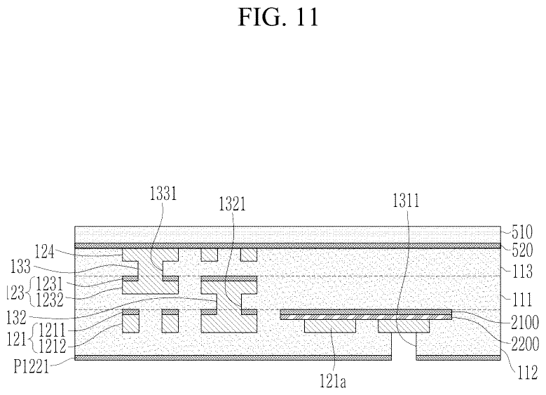

Referring to FIG. 11, the second insulating layer part 112 may be formed to bury the first circuit layer 121, the first stopper layer 2100, and the second stopper layer 2200. The second insulating layer part 112 may be formed by stacking on the first insulating layer part 111 so that the first pad 121a is buried. The second insulating layer part 112 may be formed of a material such as a Prepreg (PPG), an Ajinomoto Build-up Film (ABF), and a Resin Coated Copper foil (RCC). Accordingly, the insulating layer 110 including the first insulating layer part 111, the second insulating layer part 112, and the third insulating layer part may be formed. Although the insulating layer 110 is illustrated to include three layers in the embodiment, the insulation layer is not limited thereto.

Furthermore, referring to FIG. 11, the first via hole 1311 may be formed to penetrate the third conductive forming layer P1221 and the second insulating layer part 112. The first via hole 1311 may be formed by laser processing, mechanical drill processing, or the like.

Then, a third conductive forming layer P1221 may be formed on the surface of the second insulating layer part 112. The third conductive forming layer P1221 may be formed by performing electroless plating on the surface of the second insulating layer part 112. In FIG. 11, the third conductive forming layer P1221, which is an electroless plating layer, is illustrated to be formed only on the surface of the second insulating layer part 112, the electroless plating layer may also be formed on the inner surface of the third via hole 1311.

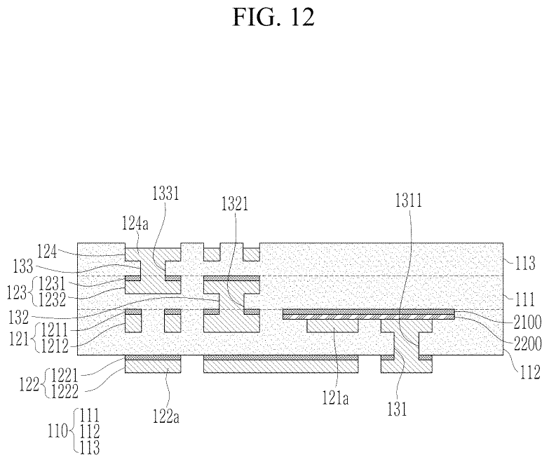

Referring to FIG. 11 and FIG. 12, the fourth conductive layer 1222 may be formed on the third conductive forming layer P1221. The fourth conductive layer 1222 may be formed by a plating process. Furthermore, the first via electrode 131 may be formed by filling a conductive material in the first via hole 1311.

For example, the fourth conductive layer 1222 and the first via electrode 131 may be formed by forming a photoresist on the third conductive forming layer P1221, patterning the photoresist through exposure and development processes, plating and filling the patterned area, and peeling the photoresist. However, the process is not limited thereto, and any method capable of configuring a pattern on a circuit board may be used without limitation.

In addition, referring to FIG. 12, the third conductive layer 1221 may be formed by removing a portion of the third conductive forming layer P1221. Accordingly, the second circuit layer 122 including the third conductive layer 1221 and the fourth conductive layer 1222 may be formed. For example, the third conductive layer 1221 may be removed by flash etching.

Here, the second circuit layer 122 may be formed to include the second pad 122a. The second pad 122a may be formed to be exposed from the insulating layer 110 on the surface of the insulating layer 110. The second circuit layer 122 may be formed to include the second pad 122a and a pattern part disposed around the second pad 122a. The second pad 122a may be formed to include a portion of the third conductive layer 1221 and a portion of the fourth conductive layer 1222. The second pad 122a may be formed by stacking an electroless plating layer and an electro plating layer.

Furthermore, the carrier insulating layer 510 and the carrier conductive layer 520 may be removed. For example, the carrier conductive layer 520 may be removed by quick etching. Accordingly, the third pad 124a, which is a portion of the fourth circuit layer 124 exposed from the other surface of the insulating layer 110, may be formed. In other words, the fourth circuit layer 124 may be formed to include the third pad 124a. Although, in FIG. 12, the fourth circuit layer 124 is illustrated to be exposed on the other surface of the insulating layer 110, but is not limited thereto, the fourth circuit layer 124 may be formed to include the third pad 124a and a pattern part disposed around the third pad 124a. The third pad 124a may be formed to include an electro plating layer.

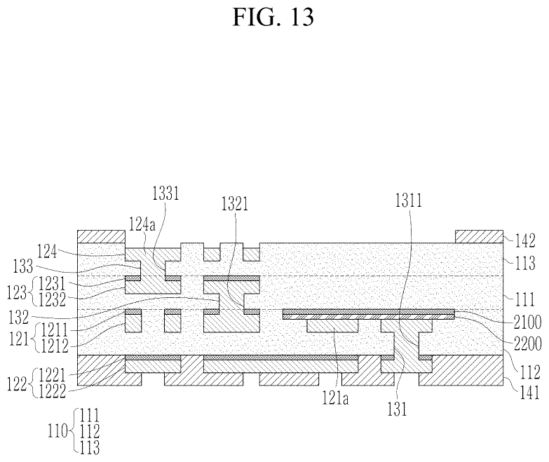

Referring to FIG. 13, the first passivation layer 141 may be formed on the second insulating layer part 112 to expose the portion of the second circuit layer 122. A second passivation layer 142 may be formed on the third insulating layer part 113 to expose the portion of the fourth circuit layer 124. The first passivation layer 141 and the second passivation layer 142 may be formed by exposure and development processes. The first passivation layer 141 may include an opening exposing the portion of the second circuit layer 122. The second passivation layer 142 may include an opening exposing the portion of the fourth circuit layer 124. The first passivation layer 141 and the second passivation layer 142 may be solder resist layers.

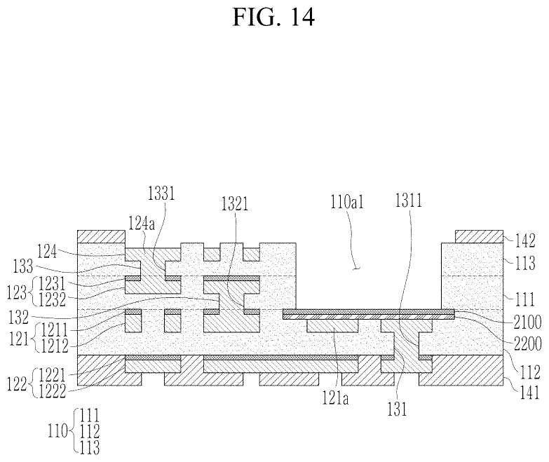

Referring to FIG. 14, a first cavity forming part 110a1 may be formed by removing a portion of the insulating layer 110 from the other surface of the insulating layer 110 to the first stopper layer 2100. For example, the portion of the insulating layer 110 may be removed by CO₂ laser. By processing up to the first stopper layer 2100 during laser processing, it is possible to prevent damage to a portion of the insulating layer 110 positioned on the first stopper layer 2100. To this end, an area in a direction perpendicular to the stacking direction of the first cavity forming part 110a1 may be smaller than the area of the first stopper layer 2100. In other words, a width in a direction perpendicular to the stacking direction of the first cavity forming part 110a1 may be smaller than the width of the first stopper layer 2100. The width and area described herein may be determined by an optical microscope or a scanning electron microscope. Other methods and/or tools appreciated by one of ordinary skill in the art, even if not described in the present disclosure, may also be used.

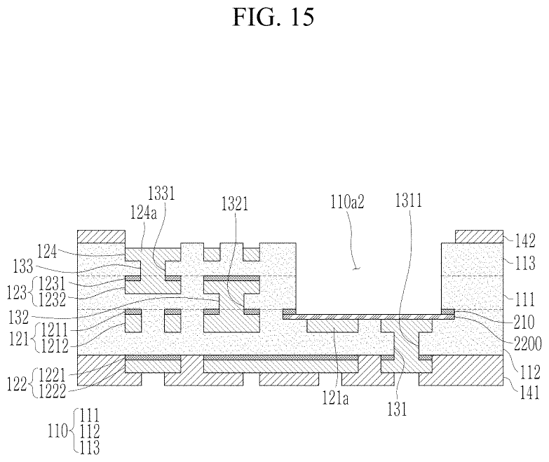

Referring to FIG. 15, the first metal layer 210 and a second cavity forming part 110a2 may be formed by etching and removing a portion of the first stopper layer 2100 exposed in the first cavity forming part 110a1. Forming the second cavity forming part 110a2 may include removing the exposed portion of the first stopper layer 2100 and forming the remaining first metal layer 210 along the edge of the first cavity forming part 110a1. The first metal layer 210 may be formed to surround the cavity 110a.

Etching processes may be a dry etching or a wet etching, but is not limited thereto. For example, an etching resist may be formed on the remaining area except for an area to be etched of the first stopper layer 2100, and the portion of the first stopper layer 2100 to be etched may be etched and removed. The etching resist may include a dry film.

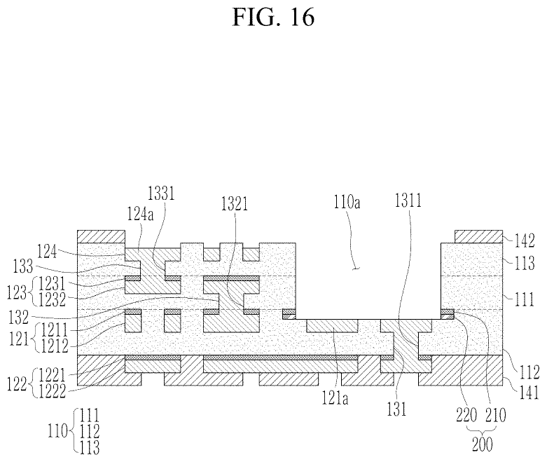

Referring to FIG. 16, the second metal layer 220 and the cavity 110a may be formed by removing a portion of the second stopper layer 2200 that is exposed in the second cavity forming part 110a2. Accordingly, a metal pattern layer 200 may be formed to include the first metal layer 210 and the second metal layer 220. Forming the cavity 110a may include removing the exposed portion of the second stopper layer 2200 and forming the remaining second metal layer 220 along the edge of the second cavity forming part 110a2. The second metal layer 220 may be formed to surround the cavity 110a. The second metal layer 220 may be formed at a position corresponding to the first metal layer 210. The second metal layer 220 may be formed to be overlapped with the first metal layer 210 in a stacking direction.

The first pad 121a may be formed such that the lower surface S121a of the first pad 121a is positioned at a higher level than the lower surface S220 of the second metal layer 220 in a stacking direction. The first pad 121a may be formed such that the lower surface S121a of the first pad 121a is positioned at a greater distance than the lower surface S220 of the second metal layer 220 from the upper surface of the first insulating layer part 111.

Etching processes may be a dry etching or a wet etching, but is not limited thereto. For example, an etching resist may be formed on the remaining area except for an area to be etched of the first stopper layer 2100, and the portion of the first stopper layer 2100 to be etched may be etched and removed. The etching resist may be a dry film.

For example, the first stopper layer 2100 may be etched using a first etchant, and the second stopper layer 2200 may be etched using a second etchant different from the first etchant. The first stopper layer 2100 and the second stopper layer 2200 may include a metal material that may be selectively removed by different etchant, and as described above, for example, the first stopper layer 2100 may include the first metal, and the second stopper layer 2200 may include the second metal having etch selectivity different from that of the first metal. Therefore, the first stopper layer 2100 and the second stopper layer 2200 may be sequentially removed using metals having different etch selectivity, so that the first pad 121a may be exposed from the insulating layer 110 without damage.

Furthermore, referring to FIG. 16 and FIG. 1, the circuit board 10A according to an embodiment as illustrated in FIG. 1 may be formed by forming the first to the third surface treatment layers 151, 152, and 153 to cover portions of the circuit layer exposed to the outside of the insulating layer 110. The first surface treatment layer 151 may be formed on the first pad 121a. The second surface treatment layer 152 may be formed on the second pad 122a. The third surface treatment layer 153 may be formed on the third pad 124a. For example, the first to the third surface treatment layers 151, 152, and 153 may be an Electroless Nickel Electroless Palladium Immersion Gold (ENEPIG), an Electroless Nickel Immersion Gold (ENIG), or the like.

The first pad 121a may be formed to have a thickness smaller than that of the first circuit layer 121, with respect to a thickness in the stacking direction. The first pad 121a may be formed to have the thickness smaller than that of the second conductive layer 1212, with respect to a thickness in the stacking direction. The metal pattern layer 200 may be formed to have a thickness smaller than that of the first circuit layer 121, with respect to a thickness in the stacking direction. The first metal layer 120 may be formed to have a thickness smaller than that of the first conductive layer 1211, with respect to a thickness in the stacking direction.

Referring to FIG. 16, FIG. 1, and FIG. 2, the first metal layer 210 may be formed by etching the first stopper layer 2100. Thus, the first metal layer 210 may be formed to be inward from a side surface of the second insulating layer part 112. For example, the first metal layer 210 may have an inclined surface of a curved surface by a wet etching process. The first metal layer 210 may be formed such that a surface exposed toward the cavity 110a includes the inclined surface inclined with respect to a reference line parallel to the stacking direction. The first metal layer 210 may be formed to have the inclined surface inclined in a curved shape. Furthermore, the second metal layer 220 may be formed by etching the second stopper layer 2200. Thus, the second metal layer 220 may be formed to be inward from a side surface of the second insulating layer part 112. For example, the second metal layer 220 may have an inclined surface of a curved surface by a wet etching process. The second metal layer 220 may be formed such that a surface exposed toward the cavity 110a includes the inclined surface inclined with respect to a reference line parallel to the stacking direction. The second metal layer 220 may be formed to have the inclined surface inclined in a curved shape.

According to an embodiment of a manufacturing method of a circuit board, by using a plurality of metal layers each including different metals as etch stopper layers, the efficiency of the process can be increased, and the pad may be more easily exposed in the cavity. Consequently, the circuit board can be formed in a thinner shape.

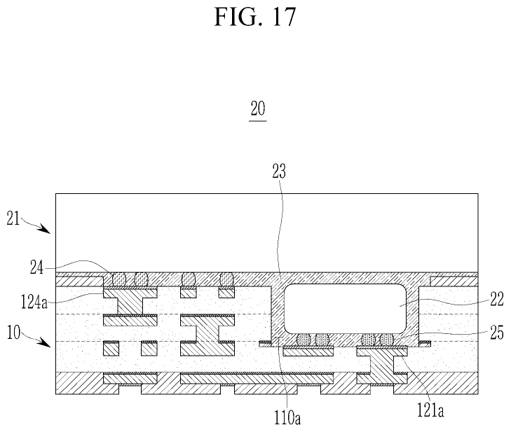

Hereinafter, an electronic component package according to an embodiment will be described with reference to FIG. 17. FIG. 17 is a cross-sectional view schematically illustrating an electronic component package according to an embodiment.

Referring to FIG. 17, an electronic component package 20 according to an embodiment may include a first circuit board 10. The first circuit board 10 may include the circuit board 10A according to an embodiment as described above. Hereinafter, the description of the circuit board 10A according to an embodiment as described above may be applied in the same manner for a description of the circuit board 10.

The electronic component package 20 according to an embodiment may include the first circuit board 10, a second circuit board 21, an electronic component 22, an encapsulant 23, a conductive member 24, and an electrode 25. The second circuit board 21 may be connected to the first circuit board 10. The first circuit board 10 may include the cavity 110a and the first pad 121a exposed from the insulating layer 110 in the cavity 110a. The electronic component 22 may be mounted on a surface of the first circuit board 10 to connect a pad part of the first circuit board 10. The electronic component 22 may be accommodated in the cavity 110a. The encapsulant 23 may be disposed between the first and the second circuit board 10, and 21. The encapsulant 23 may cover at least a portion of the electronic component 22. The conductive member 24 may electrically connect the first and second circuit boards 10, and 21. The electrode 25 may electrically connect the first circuit board 10 to the electronic component 22.

The second circuit board 21 may be a circuit board on which the electronic component 22 is mounted, and may include an insulating layer, a wiring layer, a via layer, and a solder resist layer.

For example, the electronic component 22 may be an integrated circuit (IC) die in which hundreds to millions of elements are integrated into a single chip. For example, the electronic component 22 may be a Central Processor (e.g., CPU), a Graphics Processor (e.g., GPU), a Field Programmable Gate Array (FPGA), a Digital Signal Processor, an Encryption Processor, a Micro-processor, a Micro-controller, etc., and specifically an Application Processor (AP), but is not limited thereto, and may be a memory such as other volatile memories (e.g., DRAM), non-volatile memory (e.g., ROM), flash memory, analog-to-digital converter, or logic such as ASIC (application-specific IC). If necessary, the electronic component 22 may be a chip-type passive component, e.g., a chip-type capacitor such as a Multi-Layer Ceramic Capacitor (MLCC), a chip-type inductor such as a Power Inductor (PI), etc. The electronic component 22 may be covered by the encapsulant 23, and at least a surface of the electronic component 22 may be in physical contact with the encapsulant 23.

The encapsulant 23 may cover at least a surface of the first circuit board 10 and an outer surface of the electronic component 22. The encapsulant 23 may fill at least a portion of the cavity 110a, thereby covering at least a portion of an upper surface of the electronic component 22. For example, the encapsulant 23 may physically contact at least a portion of each of upper, lower, and side surfaces of the electronic component 22. The encapsulant 23 may have fluidity in a state before curing, so it may flow along the outer surface of the electronic component 22 to fill the inside of the cavity 110a.

An insulating material may be used as a material for the encapsulant 23, and a thermosetting resin such as an epoxy resin or a thermoplastic resin such as polyimide may be used as the insulating material. Additionally, these resins including inorganic fillers such as silica may be used. For example, an Ajinomoto Build-up Film (ABF) may be used as the material for the encapsulant 23. The ABF may be provided in the form of resin coated copper (RCC), but is not limited thereto. If necessary, photosensitive materials such as Photo Imageable Dielectric (PID) may be used. Additionally, the encapsulant 23 may be a known epoxy molding compound (EMC), but is not limited thereto.

The conductive member 24 may be disposed in at least a portion of an opening of the first circuit board 10. The conductive member 24 may physically and/or electrically connect the second circuit board 21 to the outside. For example, the conductive member 24 may electrically connect an exposed circuit pattern layer of the second circuit board 21 and the third pad 124a of the first circuit board 10. Each conductive member 24 may be formed of tin (Sn) or an alloy including tin (Sn), e.g., solder, etc., but is not limited thereto. For example, the conductive member 24 may be a ball, land, pin, or pillar-shaped metal post, or a pillar-shaped combination of a plurality of balls.

The electrode 25 may be disposed in the cavity 110a of the first circuit board 10. The electrode 25 may physically and/or electrically connect the first circuit board 10 to the electronic component 22. For example, the electrode 25 may electrically connect the pad part of the electronic component 22 to the first pad 121a of the first circuit board 10.

According to an embodiment of an electronic component package, as the pad part is positioned inside the cavity of the first circuit board in which the electronic component is accommodated, a thin package may be provided while securing a mounting space for the electronic component.

While the embodiments of the present disclosure have been described above, the present disclosure is not limited thereto, and it is possible to perform various modifications within the scope of the claims, the detailed description, and the accompanying drawings, and it is natural that these modifications also fall within the scope of the present disclosure.

What is claimed is:

1. A circuit board comprising:
an insulating layer having a first insulating layer part, a second insulating layer part stacked on the first insulating layer part, and a cavity penetrating a portion of the second insulating layer part and the first insulating layer part;
a circuit layer at least partially buried in the second insulating layer part; and
a metal pattern layer disposed along an edge of the cavity in the second insulating layer part,
wherein the insulating layer has a first surface configuring a first surface of the cavity and a second surface configuring a side surface of the cavity,
the metal pattern layer comprises a plurality of metal layers exposed from the insulating layer on the second surface, and
metal layers among the plurality of metal layers include different metals.

2. The circuit board of claim 1, wherein
the metal layers among the plurality of metal layers have different etch selectivities with respect to the same material.

3. The circuit board of claim 1, wherein
the metal pattern layer is disposed at a corner region of the cavity to connect the first surface of the insulating layer and the second surface of the insulating layer.

4. The circuit board of claim 1, wherein
the plurality of metal layers comprises a first metal layer comprising copper, and a second metal layer comprising nickel and disposed on the first metal layer.

5. The circuit board of claim 4, wherein
the circuit layer comprises a first conductive layer disposed on the first insulating layer part and a second conductive layer stacked on the first conductive layer, and
a surface of the second conductive layer and a surface of the second metal layer are disposed on substantially the same plane.

6. The circuit board of claim 4, wherein
the circuit layer comprises a first conductive layer comprising the same material as the first metal layer.

7. The circuit board of claim 1, further comprising
a first pad exposed from the second insulating layer part on the first surface of the insulating layer.

8. The circuit board of claim 7, wherein
the first pad is partially buried in the insulating layer.

9. The circuit board of claim 7, wherein
a surface of the first pad exposed from the second insulating layer part positions further from the first insulating layer part in a stacking direction than a surface of the circuit layer facing the first insulating layer part.

10. The circuit board of claim 1, wherein,
in a stacking direction, a thickness of the first pad is smaller than a thickness of the circuit layer.

11. The circuit board of claim 1, wherein
the circuit layer comprises a first conductive layer comprising copper, and a second conductive layer disposed on the first conductive layer.

12. The circuit board of claim 11, wherein
the first conductive layer comprises an electroless plating layer.

13. The circuit board of claim 1, wherein
the metal pattern layer concavely positions inward from the second surface.

14. The circuit board of claim 1, further comprising
a first pad the first surface of the insulating layer, wherein the first pad is exposed from the insulating layer.

15. A manufacturing method of a circuit board, comprising:
forming a first stopper layer comprising a first metal on a first insulating layer part;
forming a second stopper layer comprising a second metal, which is different from the first metal, on the first stopper layer;
forming a first pad on the second stopper layer;
forming a second insulating layer part comprising stacking the second insulating layer part on the first insulating layer part to bury the first pad;
forming a first cavity forming part comprising removing a portion of the first insulating layer part on the first stopper layer, wherein the portion of the first insulating layer part has an area in a direction perpendicular to the stacking direction smaller than an area of the first stopper layer;
forming a second cavity forming part comprising removing an exposed portion of the first stopper layer in the first cavity forming part; and
forming a cavity comprising removing an exposed portion of the second stopper layer in the second cavity forming part.

16. The manufacturing method of claim 15, wherein
the second metal has an etch selectivity different from that of the first metal with respect to the same material.

17. The manufacturing method of claim 15, wherein
the forming of the second cavity forming part further comprises forming a first metal layer remaining along an edge of the first cavity forming part.

18. The manufacturing method of claim 17, wherein
the forming of the cavity further comprises forming a second metal layer remaining along an edge of the second cavity forming part.

19. The manufacturing method of claim 18, wherein
the first metal comprises copper, and
the second metal comprises nickel.

20. The manufacturing method of claim 15, further comprising
forming a circuit layer on the first insulating layer part comprising forming a first conductive layer on the first insulating layer part, and forming a second conductive layer on the first conductive layer to have a surface at substantially the same level as a surface of the second stopper layer.

21. The manufacturing method of claim 20, wherein
the first conductive layer comprises the same material as the first stopper layer.

22. The manufacturing method of claim 15, further comprising
forming a circuit layer on the first insulating layer part,
wherein the forming of the first pad comprises forming the first pad so that a surface of the first pad exposed from the second insulating layer part is further from the first insulating layer part in a stacking direction than a surface of the circuit layer facing the first insulating layer part.

23. The manufacturing method of claim 15, further comprising
forming a circuit layer on the first insulation layer part,
wherein the forming of the first pad comprises forming the first pad to have a thickness in a stacking direction smaller than a thickness of the circuit layer in the stacking direction.

24. The manufacturing method of claim 15, further comprising
forming a surface treatment layer on the first pad.

25. The manufacturing method of claim 15, further comprising
forming a circuit layer on the first insulating layer part comprising forming a first conductive layer comprising copper and forming a second conductive layer on the first conductive layer.

26. The manufacturing method of claim 25, wherein
the forming of the first conductive layer comprises forming an electroless plating layer.

27. The manufacturing method of claim 15, further comprising
forming a first metal layer comprising etching the first stopper layer so that the first metal layer is inward from a side surface of the second insulating layer part.

28. The manufacturing method of claim 27, further comprising
forming a second metal layer comprising etching the second stopper layer so that the second stopper layer is inward from a side surface of the second insulating layer part.

29. The manufacturing method of claim 15,
wherein the first insulating layer part and the second insulating layer part together form an insulating layer, and the cavity is formed on a surface of the insulating layer; and
the manufacturing method further comprises forming a second pad on a surface of the insulating layer such that the second pad is exposed from the insulating layer.

30. An electronic component package comprising:
a circuit board comprising:
an insulating layer having a cavity,
a pad part exposed from the insulating layer,
a circuit layer at least partially buried in the insulating layer, and
a metal pattern layer disposed along an edge of the cavity in the insulating layer,
wherein the insulating layer has a first surface configuring a first surface of the cavity and a second surface configuring a side surface of the cavity, the metal pattern layer comprises a plurality of metal layers exposed from the insulating layer on the second surface, and metal layers among the plurality of metal layers include different metals; and
an electronic component mounted in the cavity to be connected to the pad part.

31. The electronic component package of claim 30, wherein
the plurality of metal layers comprises a first metal layer comprising copper, and a second metal layer comprising nickel and disposed on the first metal layer.

32. A circuit board comprising:
an insulating layer having a first insulating layer part, a second insulating layer part stacked on the first insulating layer part, and a cavity penetrating a portion of the second insulating layer part and the first insulating layer part;
a circuit layer at least partially buried in the second insulating layer part; and
a metal pattern layer disposed along an edge of the cavity in the second insulating layer part,
wherein the insulating layer has a first surface configuring a first surface of the cavity and a second surface configuring a side surface of the cavity,
a first distance between side surfaces of the cavity at an opening of the cavity is substantially the same as a second distance between the side surfaces of the cavity adjacent to the first surface of the cavity,
the metal pattern layer comprises a plurality of metal layers exposed from the insulating layer on the second surface.

33. The circuit board of claim 32, wherein
metal layers among the plurality of metal layers include different metals, and
the metal layers among the plurality of metal layers have different etch selectivities with respect to the same material.

34. The circuit board of claim 32, wherein
the metal pattern layer is disposed at a corner region of the cavity to connect the first surface of the insulating layer and the second surface of the insulating layer.

35. The circuit board of claim 32, wherein
the plurality of metal layers comprises a first metal layer comprising copper, and a second metal layer comprising nickel and disposed on the first metal layer.

36. A manufacturing method of a circuit board, comprising:
forming a first stopper layer comprising a first metal on a first insulating layer part;
forming a second stopper layer comprising a second metal on the first stopper layer;
forming a first pad on the second stopper layer;
forming a second insulating layer part comprising stacking the second insulating layer part on the first insulating layer part to bury the first pad;
forming a first cavity forming part comprising removing a portion of the first insulating layer part on the first stopper layer, wherein the portion of the first insulating layer part has an area in a direction perpendicular to the stacking direction smaller than an area of the first stopper layer;
forming a second cavity forming part comprising removing an exposed portion of the first stopper layer in the first cavity forming part; and
forming a cavity comprising removing an exposed portion of the second stopper layer in the second cavity forming part,
wherein a first distance between side surfaces of the cavity at an opening of the cavity is substantially the same as a second distance between the side surfaces of the cavity adjacent to a surface of the cavity opposing the opening of the cavity.

37. The manufacturing method of claim 36, wherein
the second metal has an etch selectivity different from that of the first metal with respect to the same material,
the first metal includes copper, and
the second metal includes nickel.

38. The manufacturing method of claim 36, wherein
the forming of the second cavity forming part further comprises forming a first metal layer remaining along an edge of the first cavity forming part.

39. The manufacturing method of claim 38, wherein
the forming of the cavity further comprises forming a second metal layer remaining along an edge of the second cavity forming part.
